(19) United States
(12) Patent Application Publication
(10) Pub. No.: US 2015/0263017 A1
(43) Pub. Date: Sep. 17, 2015

(54) SEMICONDUCTOR STORAGE DEVICE AND METHOD OF MANUFACTURING THE SAME

(71) Applicant: KABUSHIKI KAISHA TOSHIBA, Minato-ku (JP)

(72) Inventor: Kenji AOYAMA, Yokkaichi (JP)

(73) Assignee: KABUSHIKI KAISHA TOSHIBA, Minato-ku (JP)

(21) Appl. No.: 14/483,670

(22) Filed: Sep. 11, 2014

Related U.S. Application Data
(60) Provisional application No. 61/952,716, filed on Mar. 13, 2014.

(51) Int. Cl. H01L 27/115; H01L 21/28; H01L 27/105

(52) U.S. Cl. CPC H01L 27/11524; H01L 27/1052; H01L 21/28273

(57) ABSTRACT

A semiconductor storage device is provided with memory cells; a memory string including the memory cells; and a select gate provided at both ends of the memory string. The select gate is provided with at least one electrode and the electrode has a metal silicide formed at both end portions of the electrode as viewed in a cross section of the select gate.

### CROSS-REFERENCE TO RELATED APPLICATION(S)

This application is based upon and claims the benefit of priority from U.S. Provisional Patent Application No. 61/952,716, filed on, Mar. 13, 2014 the entire contents of which are incorporated herein by reference.

### FIELD

Embodiments disclosed herein generally relate to a semiconductor storage device and a method of manufacturing the same.

### BACKGROUND

When applying metal or metal silicide to gate electrodes of semiconductor storage devices such as a NAND flash memory device, metal contamination was encountered by scattering of metal during the gate processing.

### BRIEF DESCRIPTION OF THE DRAWINGS

FIG. 1 is one example of an equivalent circuit diagram partially illustrating a memory-cell array formed in a memory-cell region of a nonvolatile semiconductor storage device of a first embodiment.

FIG. 2 is one schematic example of a plan view illustrating a layout pattern of memory cell region M in part.

FIGS. 3 to 12 are each one example of a vertical cross-sectional view illustrating one phase of the manufacturing process flow of a nonvolatile semiconductor storage device of the first embodiment.

FIGS. 13 to 22 are each one example of a vertical cross-sectional view illustrating one phase of the manufacturing process flow of a nonvolatile semiconductor storage device of a second embodiment.

### DESCRIPTION

In one embodiment, a semiconductor storage device is provided with memory cells; a memory string including the memory cells; and a select gate provided at both ends of the memory string. The select gate is provided with at least one electrode and the electrode has a metal silicide formed at both end portions of the electrode as viewed in a cross section of the select gate.

### First Embodiment

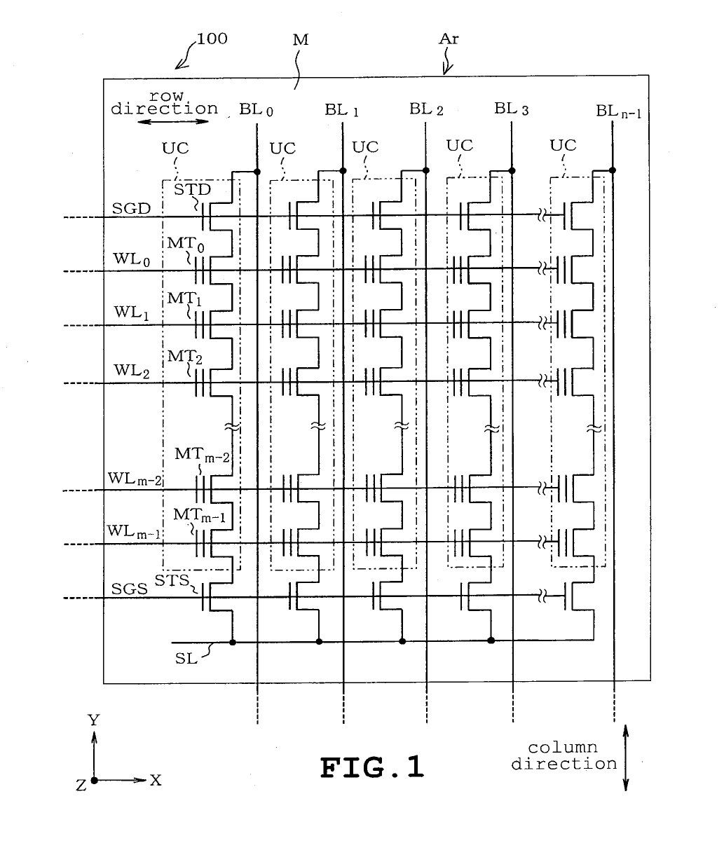

A first embodiment of a semiconductor storage device is described hereinafter through a NAND flash memory device application with reference to FIGS. 1 to 12. In the following description, elements provided with identical function and structure are identified with identical reference symbols. The drawings are schematic, and de not necessarily reflect the actual measurements of the features such as the correlation of thickness to planar dimensions and the ratio of thicknesses of each of the layers. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. In the following description, XYZ orthogonal coordinate system is used for ease of explanation. In the coordinate system, the X direction and the Y direction indicate directions parallel to the surface of the semiconductor substrate and are orthogonal to one another. The direction orthogonal to both the X direction and the Y direction are referred to as the Z direction.

First, a description will be given on the structures of a NAND flash memory device which is one embodiment of a semiconductor storage device.

FIG. 1 is one example of an equivalent circuit diagram a of memory-cell array formed in a memory-cell region of a semiconductor storage device of the first embodiment. As shown in FIG. 1, NAND flash memory device 100 is provided with memory cell array Ar configured by multiplicity of memory cells arranged in a matrix. Data can be written electrically to/erased electrically from the memory cells.

Memory cell array Ar located in memory cell region M includes unit memory cells UC. Unit memory cells UC include select-gate transistors STD connected to bit lines BL₀ to BLₙ₋ₗ and select-gate transistors STS connected to source lines SL. Between select-gate transistors STD and STS, (M=2^{k} for example) number of series connected memory-cell transistors MT₀ to MT_{M-1}, are disposed between select-gate transistors STD and STS. Memory-cell transistor MT forms memory cell MC. Unit memory cells UC are provided with a NAND string formed of the series connected memory cells MC and a couple of select-gate transistors STD and STS, either of which being provided on both ends of the NAND string.

Unit memory cells UC form a memory-cell block and the memory-cell blocks form memory-cell array Ar. That is, a single block comprises n number of unit memory cells UC, aligned along the row direction (X direction as viewed in FIG. 1). Memory-cell array Ar is formed of blocks aligned along the column direction (Y direction as viewed in FIG. 1). FIG. 1 only shows one block for simplicity.

The gates of select-gate transistors STD are connected to control line SGD. The control gates of the M^{th} memory-cell transistors MT_{M-1} connected to bit lines BL₀ to Blₙ₋₁ are connected to word line WL_{M-1}. The control gates of the third memory-cell transistors MT₂ connected to bit lines BL₀ to Blₙ₋₁ are connected to word line WL₂. The control gates of second memory-cell transistors MT_{M-1} connected to bit lines BL₀ to Blₙ₋₁ are connected to the second word line WL₁. The control gates of first memory-cell transistors MT₀ connected to bit lines BL₀ to Blₙ₋₁ are connected to first word line WL₀. The gates of select-gate transistors STS connected to source lines SL are connected to control line SGS. Control lines SGD, word lines WL₀ to WL_{M-1}, control lines SGS and source lines SL each intersect with bit lines BL₀ to Blₙ₋₁. Bit lines BL₀ to Blₙ₋₁ are connected to a sense amplifier not shown.

Gate electrodes of select-gate transistors STD of the row-direction aligned unit memory cells UC are electrically connected by common control line SGD. Similarly, gate electrodes of select-gate transistors STS of the row direction aligned unit memory cells UC are electrically connected by common control line SGS. The source of each select-gate transistor STS is connected to common source line SL. Gate electrodes of memory-cell transistors MT₀ to MT_{M-1} of the row-direction aligned unit memory cells UC are each electrically connected by word line WL₀ to WL_{M-1}, respectively.

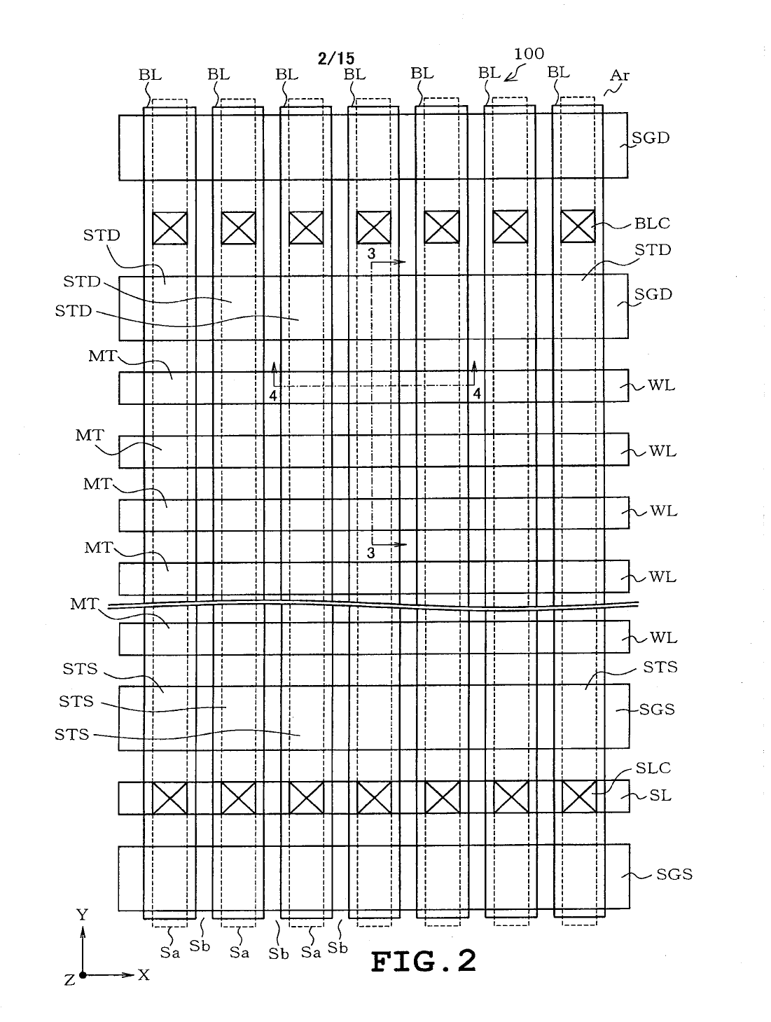

FIG. 2 is one schematic example of a plan view illustrating a planar layout of memory cell region M in part. Bit lines BL₀ to Blₙ₋₁ are also hereinafter referred to as bit line (s) BL. Word lines WL₀ to WL_{M-1} are also hereinafter referred to as word line (s) WL. Memory-cell transistors MT₀ to MT_{M-1} are also hereinafter referred to as memory-cell transistor(s) MT.

As shown in FIG. 2, source lines SL, control lines SGS, word lines WL, and control lines SGD each run in the X direction and are spaced from one another in the Y direction. Bit lines BL are aligned along the Y direction and isolated from one another in the X direction by a predetermined distance.

Element isolation regions Sb run in the Y direction as viewed in the figures. Element isolation region Sb takes an STI (shallow trench isolation) structure in which the trench is filled with an insulating film. Element isolation regions Sb are spaced from one another in the X direction by a predetermined distance. Thus, element isolation regions Sb isolate element regions Sa, formed in a surface layer of semiconductor substrate 2 along the Y direction, in the X direction. In other words, element isolation region Sb is located between element isolation regions Sa, meaning that the semiconductor substrate, is delineated into element regions Sa by element isolation region Sb.

Word lines WL extend in a direction orthogonal to element regions Sa (the X direction as viewed in FIG. 2). Word lines WL are spaced from one another in the Y direction as viewed in the figures by a predetermined distance. In element region Sa located at the intersection with word line WL, memory-cell transistor MT is disposed. The Y-direction adjacent memory-cell transistors MT form a part of a NAND string.

In element region Sa located at the intersection with control lines SGS and SGD, select-gate transistors STS and STD are disposed. Select-gate transistors STS and STD are disposed Y-direction adjacent to the outer sides of memory cell transistors MT (memory cell MG1) located at both end portions of the NAND string.

Select-gate transistors STS connected to source line SL are aligned in the X direction and select gate electrodes SG of select-gate transistors STS are electrically interconnected by control line SGS. Select gate electrode SG of select-gate transistor STS is formed in element region Sa intersecting with control line SGS. Source contact SLC is provided at the intersection of source line SL and bit line BL.

Select-gate transistors STD are aligned in the X direction as viewed in the figures and select gate electrodes SG of select-gate transistors STD are electrically interconnected by control line SGD. Select gate electrode SG of select-gate transistor STD is formed in element region Sa intersecting with control line SGD. Bit line contact BLC is provided in element region Sa located between the adjacent select-gate transistors STD.

The foregoing description outlines the basic structures of NAND flash memory device 100 to which the first embodiment is directed. The structures of NAND flash memory device 100 described above are the same in the later described second embodiment as well.

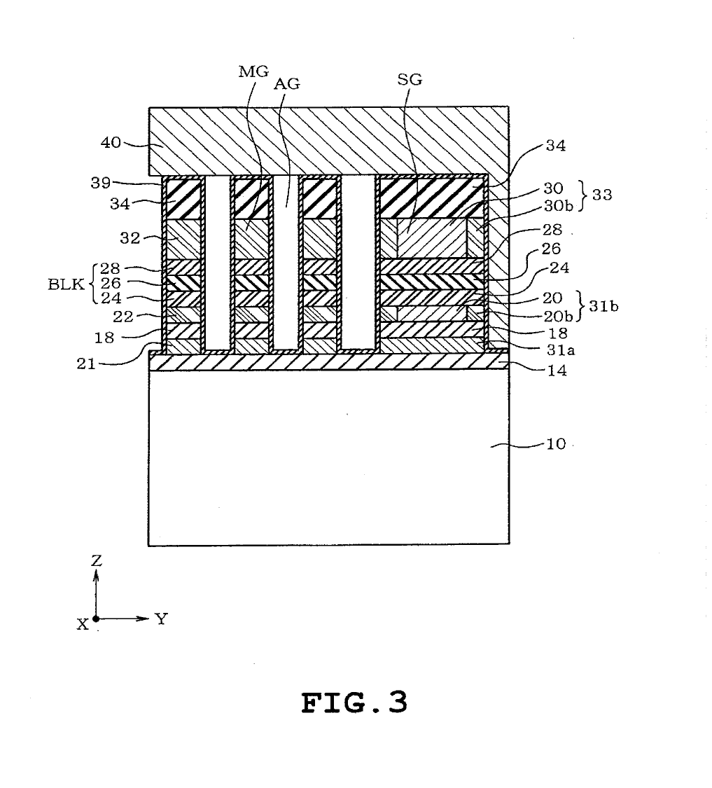

Next a description will be given in detail on the structures of NAND flash memory device 100 of the first embodiment. FIG. 3 is one example of a vertical cross-sectional view taken along line 3-3 of FIG. 2 and illustrates the structure of memory-cell region M of the present embodiment.

As illustrated in FIG. 3, gate insulating film 14 is formed above semiconductor substrate 10. A silicon substrate maybe used for example as semiconductor substrate 10. A silicon oxynitride film (SiON) may be used for example as gate insulating film 14.

Above gate insulating film 14, memory gate MG and select gate SG are formed. Memory gate MG is provided with a stack of first polysilicon film 16, interelectrode insulating film 18, first silicide 20b, first block film 24, second block film 26, third block film 28, second silicide 30b, and cap insulating film 34 above gate insulating film 14. First polysilicon film 16 serves as first floating gate electrode 21. First silicide 20b serves as second floating gate electrode 22. Second silicide 30b serves as control gate electrode 32. Gate insulating film 14 below memory gate MG serves as a tunnel insulating film. Memory gate MG serves as a gate electrode of memory-cell transistor MT and memory-cell transistor MT serves as memory cell MC. First block film 24, second block film 26, and third block film 28 collectively serve as block film BLK.

Select gate electrode SG is provided with a stack of first polysilicon film 16, interelectrode insulating film 18, second polysilicon film 20 having first silicides 20b as sidewall portions (both end portions), first block film 24, second block film 26, third block film 28, third polysilicon 30 having second silicides 30b as sidewall portions (both end portions), and cap insulating film 34 above gate insulating film 14. Select gate electrode SG serves as the gate electrode of select-gate transistor STD.

In select-gate electrode SG, first polysilicon film 16 serves as first lower electrode 31a and second polysilicon film 20 and first silicide 20b serve as second lower electrode 31b. Further, third polysilicon 30 and second silicide 30b serve as upper electrode 33.

First polysilicon film 16 is formed of for example a polysilicon. The polysilicon may be, for example, a polysilicon doped with impurities such as boron (B) and/or phosphorous (P), or a non-doped polysilicon undoped with such impurities. Interelectrode insulating film 18 is formed of for example a silicon nitride film (SiN). First silicide 20b and second silicide 30b are formed of a metal silicide such as a titanium silicide (TiSi), cobalt silicide (CoSi), nickel silicide (NiSi), molybdenum silicide (MoSi), ruthenium silicide (RuSi), tantalum silicide (TaSi), and tungsten silicide (WSi).

First block film 24 and third block film 28 are formed of a hafnium oxide containing silicon (HfSiO) for example. Second block film 26 is formed of a silicon oxide film (SiO₂) for example. Cap insulating film 34 is formed of a silicon oxide film for example.

Between memory gates MG and between memory gate MG and select-gate electrode SG, air gabs AG are formed. Second insulating film 40 is formed so as to cover the upper portions of memory gate MG, select-gate electrode SG, and air gap AG. Second insulating film 40 is formed of a silicon oxide film for example. The gaps between select gate electrodes SG (the right side of select-gate electrode SG in the figures) are wide, and thus, are filled with second insulating film 40.

As described above, in memory gate MG, first floating gate 21 is formed of first polysilicon film 16 (polysilicon), and second floating gate 22 is formed of first silicide 20b (metal silicide). Thus, electrons are more easily accumulated in first floating gate 21 than in second floating gate 22 to thereby improve the reliability of NAND flash memory device 100.

Further, control gate electrode 32 of memory gate MG is formed of second silicide 30b (metal silicide). Thus, resistance of control gate electrode 32 is reduced, to thereby enable high-speed operation of NAND flash memory device 100.

Further, the central portion of second lower electrode 31b of select-gate electrode SG is formed of third polysilicon 30 (that is, polysilicon) and thus, it is more difficult for electrons to accumulate as compared to a structure formed entirely of metal silicide. As a result, it is possible to improve the reliability of NAND flash memory device 100 since unintended electrons can be inhibited from being accumulated in second lower electrode 31b of select-gate electrode SG.

### Manufacturing Method of First Embodiment

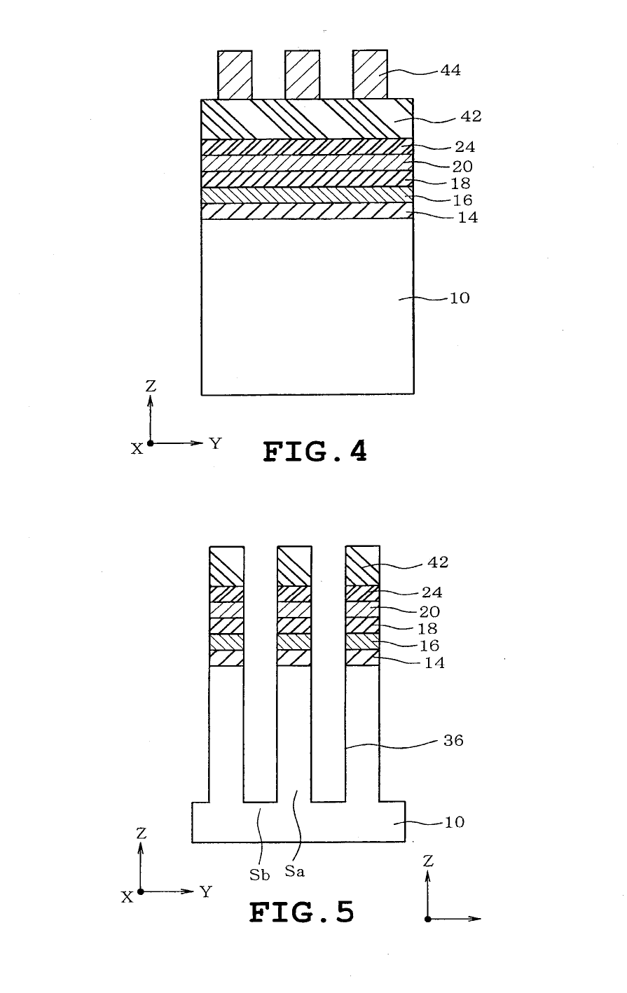

Next, a description will be given on a manufacturing process flow of NAND flash memory device 100 of the first embodiment with reference to FIGS. 3 to 12. FIG. 3 and FIGS. 7 to 12 are vertical cross-sectional views taken along line 3-3 of FIG. 2. FIGS. 4 to 6 are vertical cross-sectional views taken along line 4-4 of FIG. 2.

Referring first to FIG. 4, gate insulating film 14, first polysilicon film 16, interelectrode insulating film 18, second polysilicon film 20, first block film 24, hard mask 42, and mask film 44 are formed one after another above semiconductor substrate 10. A silicon substrate may be used for example as semiconductor substrate 10. Gate insulating film 14 may be formed of for example a silicon oxynitride film. The silicon oxynitride film may be formed for example by oxidizing a nitridized semiconductor substrate 10 (silicon substrate). A polysilicon may be used for example as first polysilicon film 16. The polysilicon may be formed by CVD (Chemical Vapor Deposition) for example. A silicon nitride film may be used for example as interelectrode insulating film 18. A polysilicon may be used for example as second polysilicon film 20. The polysilicon may be formed for example by CVD. A hafnium oxide containing silicon may be used as first block film 24. The hafnium oxide containing silicon may be formed for example by CVD. A silicon oxide film may be used for example as hard mask 42. The silicon oxide film may be formed for example by CVD. A resist patterned by lithography may be used for example as mask film 44. The resist may be replaced for example by a mask material patterned by sidewall transfer technique. Mask film 44 is patterned into the shape of element region Sa. The region riot covered by mask film 44 serves as element isolation region Sb.

Next, as illustrated in FIG. 5, etching is performed by RIE (Reactive Ion Etching) using mask film 44 as a mask. The etching progresses anisotropically one after another from hard mask 42 to gate insulating film 14 and continuously into semiconductor substrate 10 to form element isolation trenches 36 into semiconductor substrate 10. In case mask film 44 dissipates during the etching, the underlying hard mask 42 serves as the etching mask.

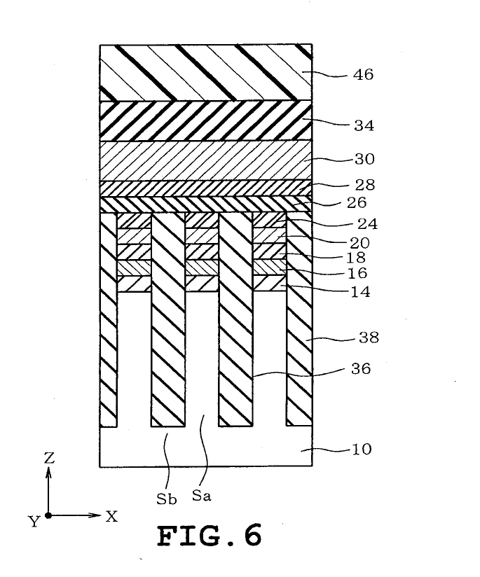

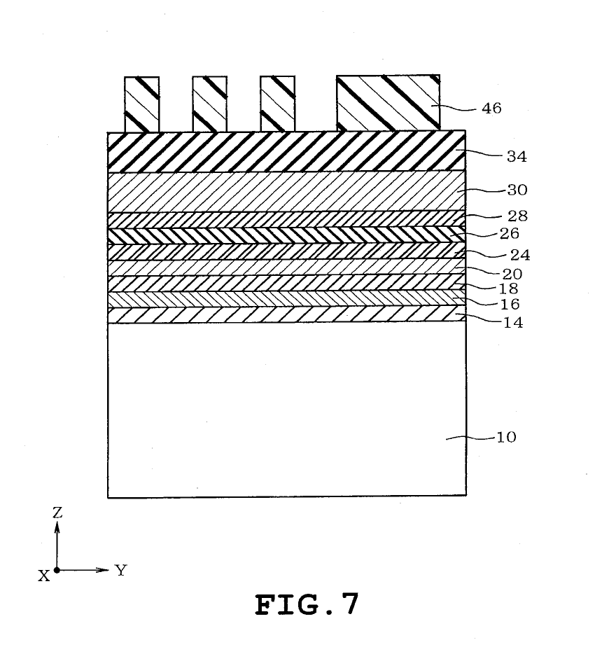

Next, as illustrated in FIGS. 6 and 7, element isolation trenches 36 are filled with element isolation insulating film 38 which is thereafter etched so that the height of the upper surface of element isolation insulating film 38 is substantially level with the height of the upper surface of first block film 24. FIGS. 6 and 7 illustrate the structures in the same process step. A silicon oxide film may be used for example as element isolation insulating film 38. Element isolation insulating film 38 (silicon oxide film) may be formed for example by forming a thin silicon oxide film by CVD which is thereafter coated with polysilazane, followed by a thermal treatment for conversion into a silicon oxide film. A dilute hydrofluoric acid solution may be used for example in the etching of element isolation insulating film 38.

Then, after removing hard mask 42, second block film 26, third block film 28, third polysilicon 30, and cap insulating film 34 are formed above first block film 24 and element isolation insulating film 38.

Second block film 26 is formed of a silicon oxide film for example. The silicon oxide film may be formed for example by CVD. Third block film 28 may be formed of a hafnium oxide containing silicon for example. The hafnium silicon oxide containing silicon may be formed for example by CVD. Cap insulating film 34 may be formed of a silicon oxide film for example. The silicon oxide film may be formed for example by CVD.

Then, mask film 46 is formed. A resist patterned by lithography may be used for example as mask film 46. The resist may be replaced for example by a mask material patterned by sidewall transfer technique. Mask film 46 is patterned into the shapes of memory gate MG (word line WL) and select gate SG.

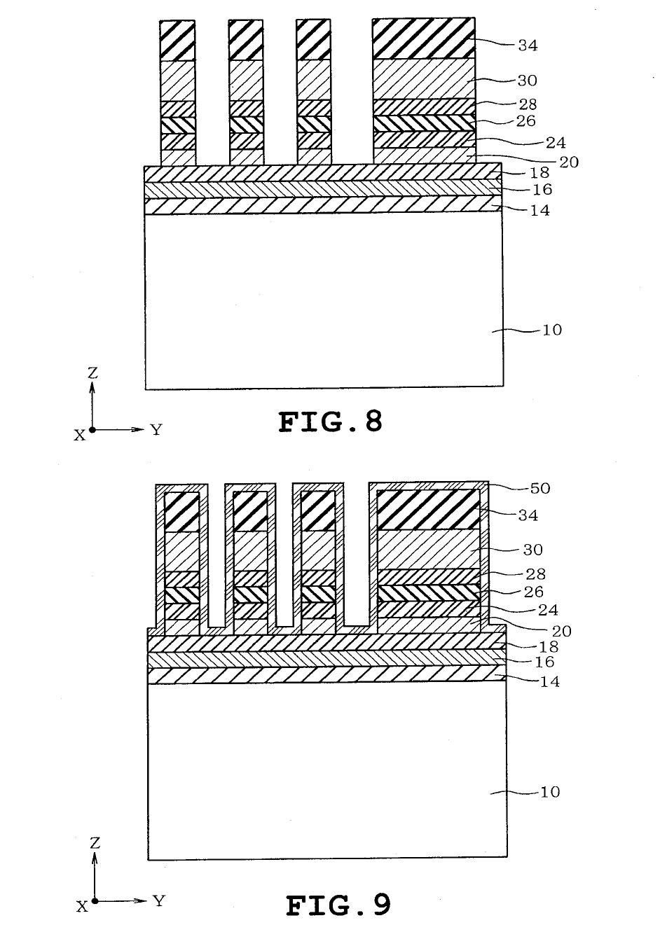

Next, as illustrated in FIG. 8, etching is performed by RIE using mask film 46 as the etching mask. The etching progresses anisotropically to remove cap insulating film 34, third polysilicon 30, third block film 28, second block film 26, first block film 24 and second polysilicon film 20 one after another and stops on the upper surface of interelectrode insulating film 18. Mask film 46 is thereafter removed.

Then, as illustrated in FIG. 9, metal film 50 (metal film) is formed along the surfaces including sidewalls and upper surfaces of cap insulating film 34, third polysilicon 30, third block film 28, second block film 26, first block film 24, and second polysilicon film 20 as well as the upper surface of interelectrode insulating film 18. For example, metal film 50 may be formed of a metal material such as titanium (Ti), cobalt (Co), nickel (Ni), molybdenum (Mo), ruthenium (Ru), tantalum (Ta), and tungsten (W). For example, metal film 50 may be formed conformally along the stereoscopic structure by sputtering, CVD, or the like. Metal film 50 is placed in contact with the sidewalls of second polysilicon film 20 and third polysilicon film 30 by this process step.

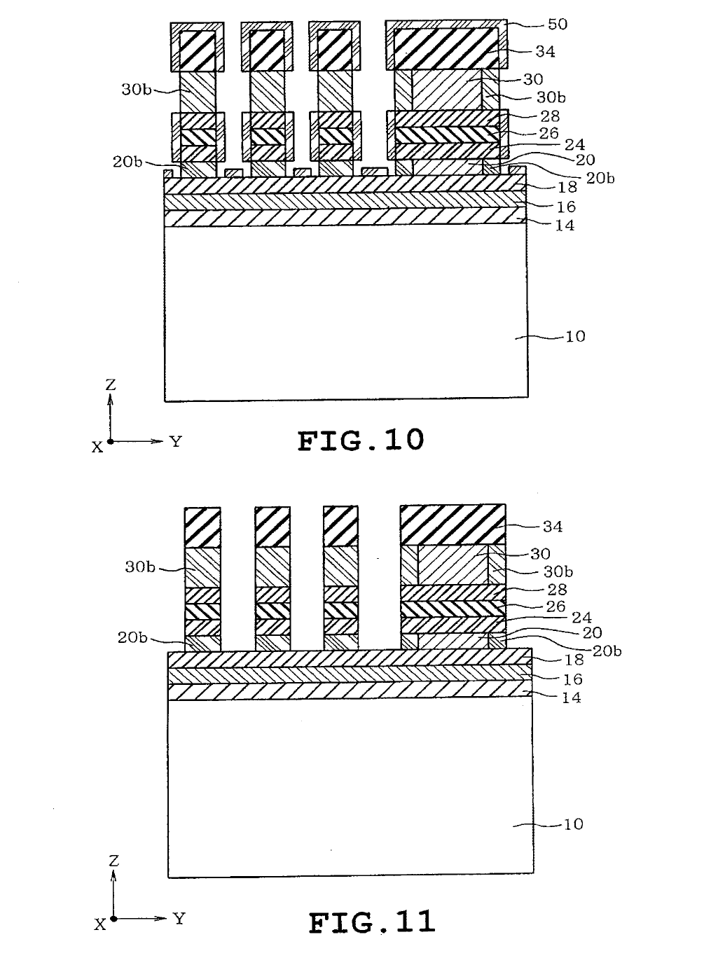

Next, as illustrated in FIG. 10, annealing is carried out to cause reaction between metal film 50 and silicon, and thereby silicide the sidewalls of second polysilicon film 20 and third polysilicon 30 to form first silicide 20b and second silicide 30b. As a result, the sidewall portions (both end portions) of second polysilicon film 20 and third polysilicon 30 become metal silicides (first silicide 20b, second silicide 30b). First silicide 20b and second silicide 30b is formed of for example a silicon nitride film (SiN). First silicide 20b and second silicide 30b are formed of a metal silicide such as a titanium silicide (TiSi), cobalt silicide (CoSi), nickel silicide (NiSi), molybdenum silicide (MoSi), ruthenium silicide (RuSi), tantalum silicide (TaSi), and tungsten silicide (WSi). The unreacted metal film 50 (excessive metal) which did not react with second polysilicon film 20 and third polysilicon 30 remain in locations exclusive of the sidewalls of second polysilicon film 20 and third polysilicon 30.

In the regions for forming memory gates MG, second poly silicon film 20 and third polysilicon 30 are completely silicided since the patterns are small. That is, the entire second polysilicon film 20 becomes first silicide 20b and the entire third polysilicon 30 becomes second silicide 30b.

On the other hand, in the regions for forming select gate electrodes SG, the portions of second polysilicon film 20 and third polysilicon 30 facing the sidewalls are silicided since the patterns are large. That is, the portions (both end portions) facing the sidewalls of second polysilicon film 20 become first silicides 20b so as to form first silicides 20b along both sides of second polysilicon film 20. Further, the portions (both end portions) facing the sidewalls of third polysilicon 30 become second silicides 30b so as to form second silicides 30b along both sides of third polysilicon 30.

Next, as illustrated in FIG. 11, the unreacted metal film 50 is removed. The unreacted metal film 50 can be removed using sulfuric-acid hydrogen peroxide solution for example.

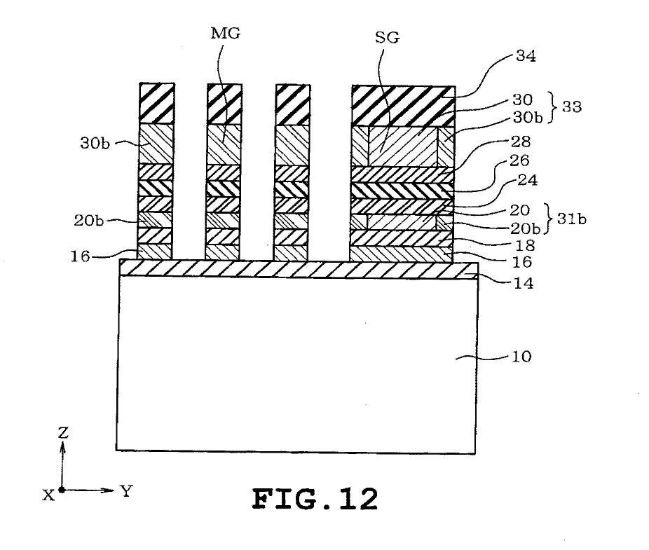

Then, Using cap insulating film 34 as an etching mask, interelectrode insulating film 18 and first polysilicon film 16 are etched using RIE as illustrated in FIG. 12. The etching progresses anisotropically and is arranged to stop on gate insulating film 14. Memory gate MG and select-gate electrode SG are formed by the above described process steps.

Next, as illustrated in FIG. 3, first insulating film 39 is formed conformally along the surfaces of memory gate MG, select-gate electrode SG, and gate insulating film 14, whereafter, second insulating film 40 is formed under conditions providing poor coverage. A silicon oxide film may be used as first insulating film 39. First insulating film 39 may be formed for example by CVD under conditions providing good step coverage. Thus, it is possible to form first insulating film 39 conformally along the stereoscopic structures formed of memory gates MG and select-gate electrodes SG. A silicon oxide film may be used for example as second insulating film 40. Second insulating film 40 may be formed for example using plasma CVD under conditions providing poor coverage. Thus, it is possible to form second insulating film 40 covering air gaps Ag, memory gates MG, and select-gate electrodes SG while leaving air gaps AG in small spaces between memory gates MG and between memory gate MG and select-gate electrode SG. Second insulating film 40 is formed between select-gate electrodes SG (the right side of select-gate electrode SG in the drawings) since the gap between select gate electrodes SG is wide.

It is possible to form NAND flash memory device 100 of the present embodiment by the above described process steps.

In the present embodiment, etching is performed when second floating gate 22 and second lower electrode 31b are still polysilicon. Thus, metal contamination can be inhibited as compared to etching second floating gate 22 and second lower electrode 31b after being formed into metal silicides. As a result, it is possible to improve the reliability of NAND flash memory device 100.

Further, the central portions of second lower electrode 31b and upper electrode 33 of select-gate electrode SG are not silicided and remain as second polysilicon film 20 and third polysilicon 30. Thus, it is possible to inhibit degradation of interelectrode insulating film 18 and block film BLK by metal diffusion as compared to the case where second lower electrode 31b and upper electrode 33 are entirely formed of metal silicides. This also improves the reliability of NAND flash memory device 100.

### Second Embodiment

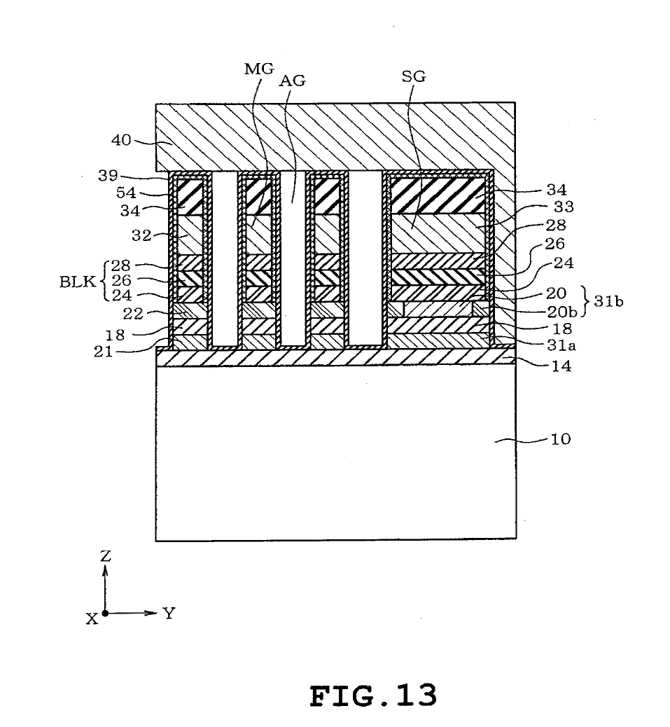

Next, a second embodiment of a semiconductor device will be described through a NAND flash memory device application with reference to FIGS. 13 to 22. In the following description, items that remain unchanged from the first embodiment will be described using the drawings, etc. used in the first embodiment. Further, the elements that are identical in function or structure to those of the first embodiment are identified with identical reference symbols and will not be re-described.

The equivalent circuit diagram of the memory-cell array and the layout pattern of memory-cell region M of NAND flash memory device 100 of the second embodiment are the same as those illustrated in FIGS. 1 and 2 explained in the first embodiment. NAND flash memory device 100 of the second embodiment has a cross-sectional structure that differs from the cross-sectional structure of the first embodiment.

FIG. 13 illustrates one example of a vertical cross-sectional view of NAND flash memory device 100. As shown in FIG. 13, gate insulating film 14 is formed above semiconductor substrate 10. Above gate insulating film 14, memory gate MG and select gate SG are formed.

Memory gate MG is provided with a stack of first polysilicon film 16, interelectrode insulating film 18, first silicide 20b, first block film 24, second block film 26, a third block film 28, metal film 52, and cap insulating film 34 above gate insulating film 14. The upper surfaces and sidewalls of the stereoscopic structure formed of first block film 29, second block film 26, third block film 28, metal film 52, and cap film 34 are covered by liner film 54. Liner film 54 is formed of a silicon nitride film for example.

First polysilicon film 16 serves as first floating gate electrode 21. First silicide 20b serves as second floating gate electrode 22. Metal film 52 serves as control gate electrode 32. Gate insulating film 14 below memory gate MG serves as a tunnel insulating film. Memory gate MG serves as a gate electrode of memory-cell transistor MT and memory-cell transistor MT serves as memory cell MC. First block film 24, second block film 26, and third block film 28 collectively serve as block film BLK.

Select gate electrode SG is provided with a stack of first polysilicon film 16, interelectrode insulating film 18, second polysilicon film 20 having first silicide 20b as a sidewall, first block film 24, second block film 26, third block film 28, metal film 52, and cap insulating film 34 above gate insulating film 14. Select gate electrode SG serves as the gate electrode of select-gate transistor STD.

In select-gate electrode SG, first polysilicon film 16 serves as first lower electrode 31a and second polysilicon film 20 and first silicide 20b serve as second lower electrode 31b. Further, metal film 52 serves as upper electrode 33.

First polysilicon film 16 is formed of for example a polysilicon. Interelectrode insulating film 18 is formed of for example a silicon nitride film (SiN). First silicide 20b is formed of a metal silicide such as a titanium silicide (TiSi), cobalt silicide (CoSi), nickel silicide (Nisi), molybdenum silicide (MoSi), ruthenium silicide (RuSi), tantalum silicide (TaSi), and tungsten silicide (WSi).

First block film 24 and third block film 28 are formed of a hafnium oxide containing silicon (HfSiO) for example. Second block film 26 is formed of a silicon oxide film for example. Metal film 52 is formed of a stack of tungsten nitride (WN)/tungsten (W) films for example. Cap insulating film 34 is formed of a silicon oxide film for example.

Between memory gates MG and between memory gate MG and select-gate electrode SG, air gaps AG are formed. Second insulating film 40 is formed so as to cover the upper portions of memory gate MG, select-gate electrode SG, and air gap AG. Along the sidewalls of memory gate MG and select-gate electrode SG inside air gap AG, first insulating film 39 is formed. First insulating film 39 and second insulating film 40 are formed of a silicon oxide film for example. The gaps between select gate electrodes SG (the right side of select-gate electrode SG in the figures) are wide, and thus, are filled with second insulating film 40.

As described above, first floating gate 21 of memory gate MG is formed of polysilicon, and second floating gate 22 is formed of first silicide 20b (metal silicide). Thus, effects similar to those of the first embodiment are achieved.

Further, control gate electrode 32 of memory gate MG is formed of metal film 52. Thus, resistance of control gate electrode 32 is reduced, to thereby enable high-speed operation of NAND flash memory device 100.

Further, the central portion of second lower electrode 31b of select-gate electrode SG is formed of third polysilicon 30 (that is, polysilicon) and thus, it is more difficult for electrons to accumulate as compared to a structure formed entirely of metal silicide. As a result, effects similar to those of the first embodiment are achieved.

### Manufacturing Method of Second Embodiment

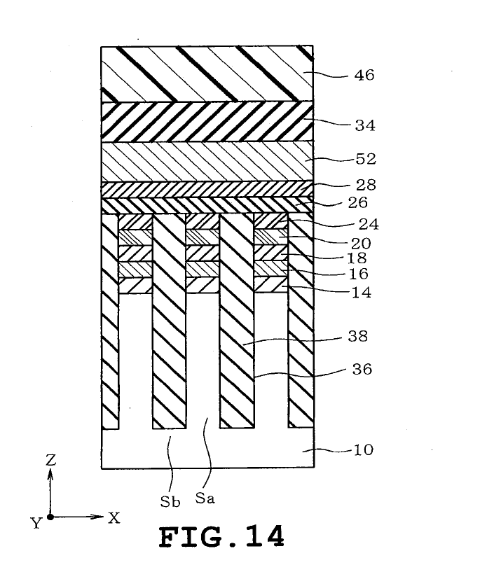

Next, a description will be given on a manufacturing process flow of NAND flash memory device 100 of the second embodiment with reference to FIGS. 13 to 22. FIG. 13 and FIG. 15 to FIG. 22 are vertical cross-sectional views taken along line 3-3 of FIG. 2. FIG. 14 is a vertical cross-sectional view taken along line 4-4 of FIG. 2.

First, a description will be given on the process steps described based on FIGS. 4 and 5.

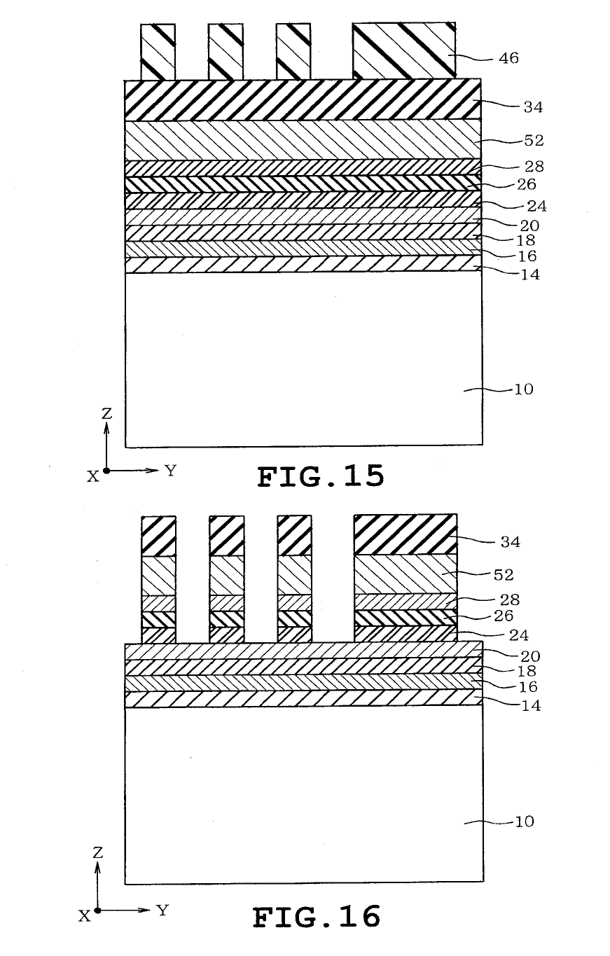

Next, as illustrated in FIGS. 14 and 15, element isolation trenches 36 are filled with element isolation insulating film 38 which is thereafter etched so that the height of the upper surface of element isolation insulating film 38 is substantially level with the height of the upper surface of first block film 24. FIGS. 14 and 15 illustrate the structures in the same process step.

Then, after removing hard mask 42, second block film 26, third block film 28, third polysilicon 30, and cap insulating film 34 are formed above first block film 24 and element isolation insulating film 38. Then, mask film 46 is formed. Mask film 46 is patterned into the shapes of memory gate MG (word line WL) and select gate SG.

Next, as illustrated in FIG. 16, etching is performed by RIE using mask film 46 as the etching mask. The etching progresses anisotropically to remove cap insulating film 34, metal film 52, third block film 28, second block film 26, and first block film 24 one after another and stops on the upper surface of second polysilicon film 20.

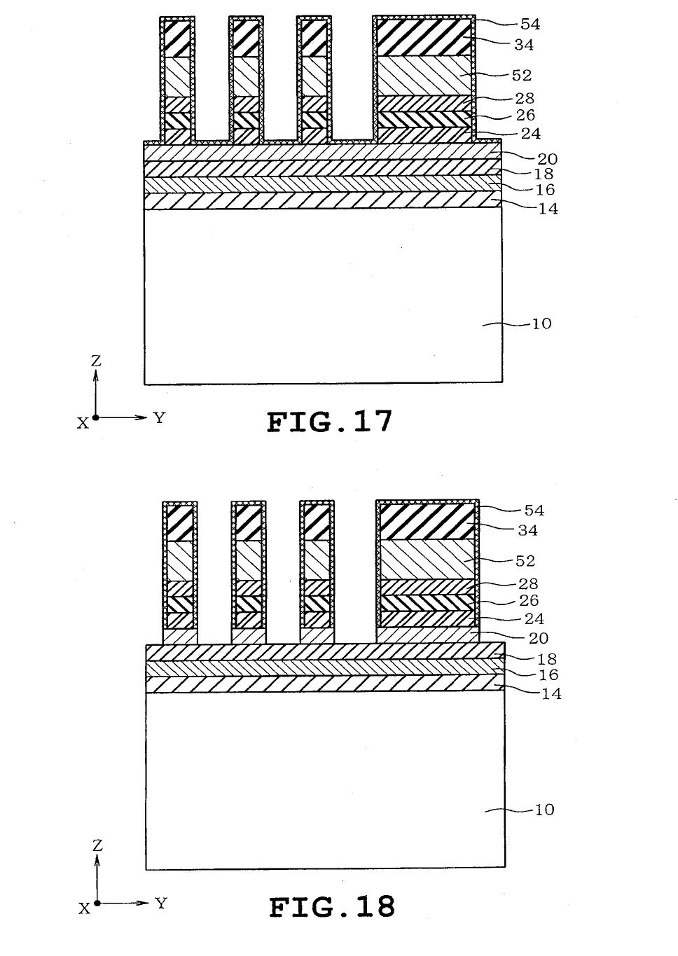

Then, as illustrated in FIG. 17, liner film 54 is formed entirely along the surfaces including the upper surfaces and sidewalls of cap insulating film 34, metal film 52, third block film 28, second block film 26, and first block film 24, as well as the upper surface of second polysilicon film 20. A silicon nitride film may be used as liner film 54. The silicon nitride film may be formed of CVD for example.

Next, as illustrated in FIG. 18, second polysilicon film 20 is etched by RIE using liner film 54 as the etching mask. The etching progresses anisotropically so as to stop on the upper surface of interelectrode insulating film 18.

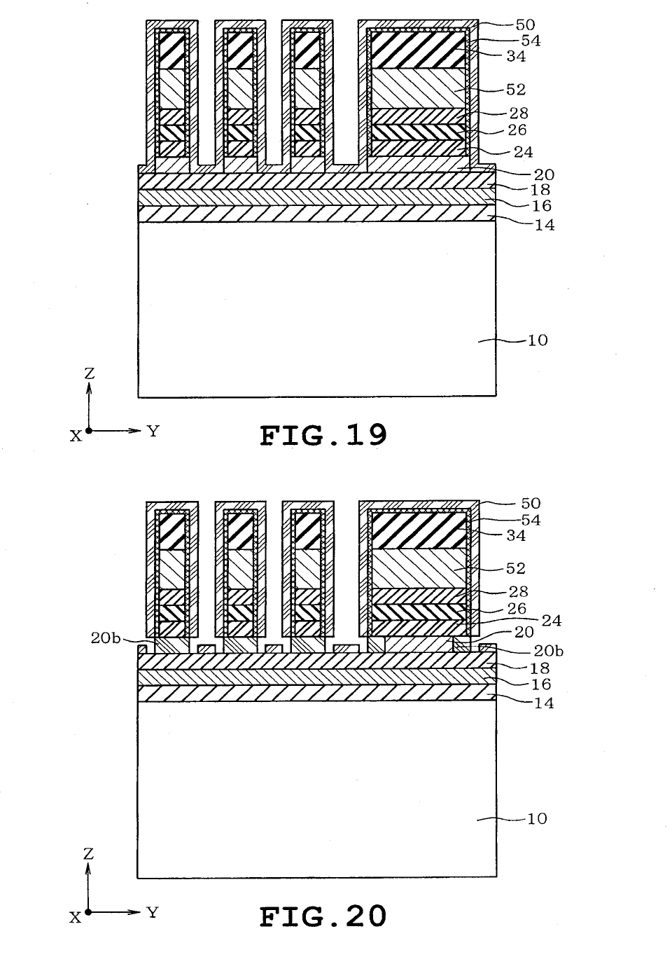

Then, as illustrated in FIG. 19, metal film 50 is formed. For example, metal film 50 maybe formed of a metal material such as titanium (Ti), cobalt (Co), nickel (Ni), molybdenum (Mo), ruthenium (Ru), tantalum (Ta), and tungsten (W). For example, metal film 50 may be formed conformally along the stereoscopic structure by sputtering, CVD, or the like. Metal film 50 is placed in contact with the sidewalls of second polysilicon film 20 by this process step. Cap film 34, metal film 52, third block film 28, second block film 26, and first block film 24, being covered by liner film 54, do not contact metal film 50.

Next, as illustrated in FIG. 20, annealing is carried out to cause reaction between metal film 50 and second polysilicon film 20 (silicon), and thereby silicide the sidewalls of second polysilicon film 20 to form first silicide 20b. The unreacted metal film 50 (excessive metal) which did not react with second polysilicon film 20 remain in locations exclusive of the sidewalls of second polysilicon film 20.

In the regions for forming memory gates MG, second poly silicon film 20 is completely silicided since the patterns are small. That is, the entire second polysilicon film 20 becomes first silicide 20b.

On the other hand, in the regions for forming select gate electrodes SG, the portions of second polysilicon film 20 facing the sidewalls are silicided since the patterns are large. That is, the portions (both end portions) facing the sidewalls of second polysilicon film 20 become first silicides 20b so as to form first silicides 20b along both sides of second polysilicon film 20.

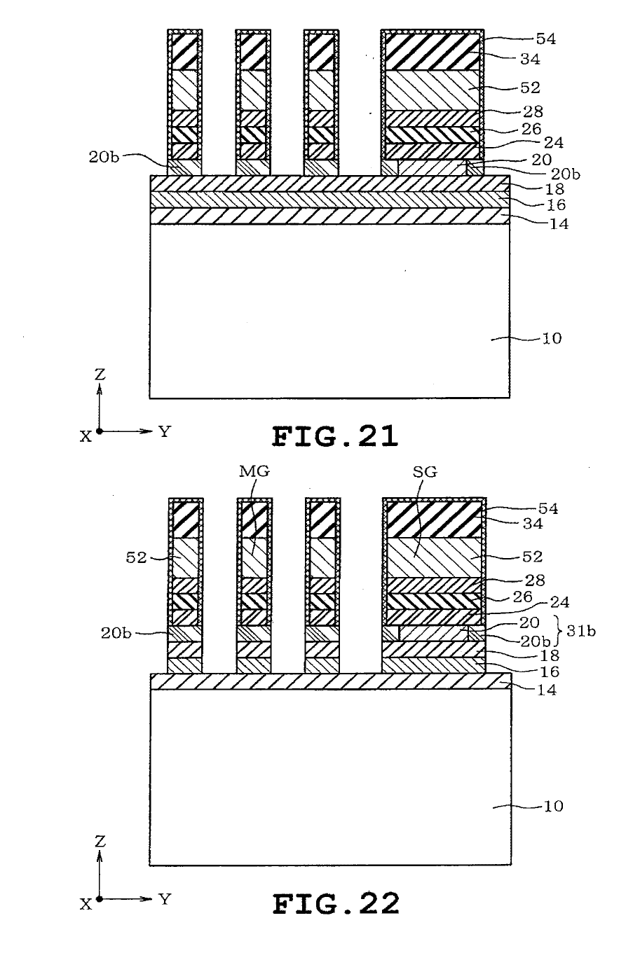

Next, as illustrated in FIG. 21, unreacted metal film 50 is removed. The unreacted metal film 50 can be removed using sulfuric-acid hydrogen peroxide solution for example.

Then, using liner film 54 as an etching mask, interelectrode insulating film 18 and first polysilicon film 16 are etched using RIE as illustrated in FIG. 22. The etching progresses anisotropically and is arranged to stop on gate insulating film 14. Memory gate MG and select-gate electrode SG are formed by the above described process steps.

Next, as illustrated in FIG. 13, first insulating film 39 is formed conformally along the surfaces of memory gate MG, select-gate electrode SG, and gate insulating film 14, whereafter, second insulating film 40 is formed under conditions providing poor coverage. Thus, it is possible to form second insulating film 40 covering air gaps Ag, memory gates MG, and select-gate electrodes SG while leaving air gaps AG in small spaces between memory gates MG and between memory gate MG and select-gate electrode SG. Second insulating film 40 is formed between select-gate electrodes SG (the right side of select-gate electrode SG in the drawings) since the gap between select gate electrodes SG is wide.

It is possible to form NAND flash memory device 100 of the present embodiment by the above described process steps. The above described process steps provide the effects similar to those of the first embodiment.

In the present embodiment, the lower layer films are etched during memory gate MG and select-gate electrode SO processing with metal film 52 covered by liner film 54. Thus, it is possible to inhibit metal contamination as compared to a case in which metal film 52 is exposed. As a result, it is possible to improve the reliability of NAND flash memory device 100.

### Other Embodiments

In the above described embodiments, examples of NAND flash memory device applications where disclosed, however, other embodiments maybe directed to nonvolatile semiconductor storage devices such as NOR flash memory device and EPROM, or to semiconductor storage devices such as DRAM or SRAM, or further to logic semiconductor devices such as a microcomputer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
memory cells;
a memory string including the memory cells; and
a select gate provided at both ends of the memory string, the select gate including at least one electrode, the electrode having a metal silicide formed at both end portions of the electrode as viewed in a cross section of the select gate.

2. The semiconductor storage device according to claim 1, wherein the electrode is provided with a polysilicon and a metal silicide formed at both end portions of the polysilicon.

3. The semiconductor storage device according to claim 2, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

4. The semiconductor storage device according to claim 1, wherein the select gate includes a first electrode, a second electrode, and a third electrode, and wherein a first insulating film is provided between the first electrode and the second electrode, a second insulating film is provided between the second electrode and the third electrode, and wherein a metal silicide is provided at both end portions of the second electrode and the third electrode.

5. The semiconductor storage device according to claim 4, wherein the second electrode and the third electrode are provided with a polysilicon and metal silicide formed at both end portions of the polysilicon.

6. The semiconductor storage device according to claim 5, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

7. A semiconductor storage device comprising:
memory cells;
a memory string including the memory cells;
a select gate provided at both ends of the memory string, the select gate including at least one electrode, an electrode of the select gate having a metal silicide formed at both ends thereof as viewed in a cross section of the select gate; and
a memory gate forming the memory cell, the memory gate including at least one electrode,
an electrode of the memory gate being formed of a metal silicide as viewed in a cross section of the memory gate.

8. The semiconductor storage device according to claim 7, wherein an electrode of the select gate is provided with a polysilicon and a metal silicide formed at both end portions of the polysilicon.

9. The semiconductor storage device according to claim 8, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

10. The semiconductor storage device according to claim 7, wherein the select gate includes a first electrode, a second electrode, and a third electrode, and wherein a first insulating film is provided between the first electrode and the second electrode, a second insulating film is provided between the second electrode and the third electrode, and wherein a metal silicide is provided at both end portions of the second electrode and the third electrode.

11. The semiconductor storage device according to claim 10, wherein the second electrode and the third electrode are provided with a polysilicon and a metal silicide formed at both end portions of the polysilicon.

12. The semiconductor storage device according to claim 11, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

13. The semiconductor storage device according to claim 7, wherein the memory gate includes a fourth electrode, a fifth electrode, and a sixth electrode, and wherein a third insulating film is provided between the fourth electrode and the fifth electrode, a fourth insulating film is provided between the fifth electrode and the sixth electrode, and wherein the fifth electrode and the sixth electrode are formed of a metal silicide.

14. The semiconductor storage device according to claim 13, wherein the fifth electrode and the sixth electrode are formed of a metal silicide.

15. The semiconductor storage device according to claim 14, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

16. A method of manufacturing a semiconductor storage device comprising:
forming a first insulating film above a semiconductor substrate;
forming a first conductive film above the first insulating film;
forming a second insulating film above the first conductive film;
forming a second conductive film above the second insulating film;
forming a third insulating film above the second conductive film;
forming a third conductive film above the third insulating film;
forming a fourth insulating film above the third conductive film;
forming a mask film above the fourth insulating film;
etching the fourth insulating film to the second insulating film using the mask film as an etching mask;
forming a metal film above an entire surface; and
forming a metal silicide by causing reaction between the metal film and the second conductive film in a portion where the metal film contacts both end portions of the second conductive film.

17. The method of manufacturing a semiconductor storage device according to claim 16, wherein the metal film is provided with at least one material selected from the group consisting of titanium, cobalt, nickel, molybdenum, ruthenium, tantalum, and tungsten.

18. The method of manufacturing a semiconductor storage device according to claim 16, wherein the metal silicide is provided with at least one material selected from the group consisting of a titanium silicide, a cobalt silicide, a nickel silicide, a molybdenum silicide, a ruthenium silicide, a tantalum silicide, and a tungsten silicide.

19. The method of manufacturing a semiconductor storage device according to claim 16, further comprising forming a metal silicide by causing a reaction between the metal film and the third conductive film at a portion where the metal film contacts both end portions of the third conductive film.

20. The method of manufacturing a semiconductor storage device according to claim 19, wherein the metal film and the metal silicide are provided with at least one material selected from the group consisting of titanium, cobalt, nickel, molybdenum, ruthenium, tantalum, and tungsten.
